(19) United States
(12) Patent Application Publication
(10) Pub. No.: US 2026/0356286 A1
(43) Pub. Date: Nov. 12, 2026

(54) SENSOR DOOR BUTTON BEING ATTACHABLE TO A WINDOW PANEL OF A VEHICLE DOOR

(71) Applicants: Oahu B.V., Bolsward (NL); Ventura Systems C.V., Bolsward (NL)

(72) Inventor: Hilbrand Hans Asjes, Bolsward (NL)

(21) Appl. No.: 19/127,196

(22) PCT Filed: Jul. 14, 2023
(86) PCT No.: PCT/EP2023/069720

§ 371 Date: May 5, 2025

(30) Foreign Application Priority Data
Nov. 15, 2022 (NL) 2033532

(51) Int. Cl. B60Q 3/20; B60K 35/21; B60K 35/22; B60Q 3/80; F21V 3/02; F21V 7/22; F21Y 115/10

(52) U.S. Cl. CPC B60Q 3/20; B60K 35/212; B60K 35/22; B60Q 3/80; F21V 3/02; F21V 7/22; F21Y 2115/10

(57) ABSTRACT

A sensor door button being attachable to a window panel which includes a printed circuit board. At least one detection sensor, at least one light source and a distinct electronic screen are positioned on a front side of the printed circuit board. The electronic screen is configured to provide information to a user. The electronic screen is positioned at a central region on the front side of the printed circuit board and the detection sensor and the light source are positioned around the electronic screen. The configuration of the electronic components is beneficial in that in operation of the sensor door button a display of a selected predetermined image on the electronic screen can be simultaneously combined with a predetermined setting of the light source to attract passenger attention.

### CROSS-REFERENCE TO RELATED APPLICATIONS

This application is the National Stage of International Application No.

PCT/EP 2023/069720, filed Jul. 14, 2023, which claims the benefit of Netherlands Application No. 2033532, filed Nov. 15, 2022, the contents of which is incorporated by reference herein.

### FIELD OF THE INVENTION

The invention relates to a sensor door button which is attachable to an inside of a window panel and arranged to be operated from outside the window panel, in particular attachable to a window panel of a vehicle door. The sensor door button has at least one detection sensor for detecting a presence of a hand and/or a finger in a detection space at a front side of the sensor door button. Further, the sensor door button has at least one light source for illuminating an environment at the front side of the sensor door button.

Further, the invention relates to a method of operating a sensor door button system including a control unit which is electronically connectable to a controller of a public transport vehicle.

### BACKGROUND OF THE INVENTION

EP0877458 in the name of Captron Electronic GmbH is published in 1998 and discloses a connection of an assembly arrangement including a flat switch unit and an annular flange. The switch unit has a flat side forming actuating surface of a switch. The annular flange is connected to the switch unit by an O-ring being positioned in a groove surrounding the switch unit. Herewith, the annular flange fits to the switch unit.

DE202010009164U1 is published in 2010 and discloses a touchscreen which serves as a door switch. The touchscreen replaces an old version of a door switch which has an optical display positioned at a housing above a capacitive sensor being illuminated by LEDs. The touchscreen is beneficial in that it can be used to present symbols, texts, promotions and video messages which makes the capacitive sensor with LEDs redundant.

Door switches in public transport vehicles should properly operate in a broad variety of circumstances. For example, a brightness of the door switch should be high to attract a user's attention on a sunny day, but should be low during the evening hours for not agitating passengers. The door switch should be operatable in different assemblies. The door switch should proper function when attached to a tinted glass panel. A drawback of this known door switch provided by a touchscreen is that this door switch does not comply to technical requirements considering visibility and sensibility for a sensor door button of a public transport vehicle.

EP4009525A1 which is a patent family member of EP4009526A1 and also in the name of Captron Electronic GmbH is published in 2022 and discloses a sensor button to be used in a public transport system. The sensor button includes a sensor surface which may be touched or approached by a person to generate a sensor signal. A side wall is provided for mounting the sensor button to a door window. The sensor surface includes at least one capacitive sensor electrode and at least one optical sensor coupled to a sensor circuit. The at least one capacitive sensor component like a conductive material functions to detect the presence of a hand and/or a finger in a capacitive detection space. The sensor surface further includes at least one optical sensor component, like a camera or photodiode for detecting the position of a hand and/or a finger within a optical detection space. Further, the sensor surface includes a light source, like an LED. A visual LED may be used for optical signalling. A combination of infrared LEDs for detection and visible LEDs for user feedback and/or a user guidance may be provided.

A drawback of this known sensor button is that although it may comply to nowadays technical requirements, a transfer of information to a user is limited.

Regarding the above-mentioned prior art, it is remarked that any discussion of documents, acts, materials, devices, articles or the like included in the present specification is for the purpose of providing a context for the present invention, and is not to be taken as an admission that any such matters form part of the prior art or is to be considered common general knowledge in the field relevant to the present invention before the priority date of each claim of this application.

### SUMMARY OF THE INVENTION

The general object of the present invention is to at least partially eliminate the above mentioned drawback and/or to provide a usable alternative. More specific, it is an object of the invention to provide a sensor door button which is attachable to a window panel and which complies to technical requirements applicable for visibility and sensibility for a public transport vehicle.

According to the invention, this object is achieved by a sensor door button according to the present disclosure.

According to the invention, a sensor door button for operating a door is provided. The sensor door button is attachable to a transparent window panel of the door. The sensor door button is preferably attachable to an inner side of the window panel of a door window of a public transport vehicle. The sensor door button is then positioned at an inner side, but through the transparent window panel operable from the outside of the door. A passenger can operate the sensor door button from the outside of the door to open the vehicle door to enter the vehicle. The sensor door button at the inside of the door is beneficial in that the sensor door button is less subject to weathering.

The sensor door button comprises a printed circuit board. The printed circuit board is arranged to support electronic components. The printed circuit board has an electric circuit for electrically connecting the electronic components. The electric circuit is positioned on a front side of the printed circuit board to allow this front side connection of electronic components.

The sensor door button comprises at least one detection sensor for detecting a presence of a hand and/or a finger in a detection space. The at least one detection sensor is positioned on the front side of the printed circuit board.

The sensor door button comprises at least one light source. Preferably, the light source is an LED. The light source serves to illuminate an environment at a front side of the sensor door button. Preferably, the light source comprises a plurality of Red-Green-Bleu LEDs for generating multiple colours. The at least one light source is positioned on the front side of the printed circuit board.

The sensor door button further comprises a programmable electronic display, also called a programmable electronic screen, in particular an LCD screen, preferably an OLED screen. The electronic screen is arranged to provide information to a user. The electronic screen may be arranged to display a logo, an icon, a stationary or dynamic image. Preferably, the electronic screen has a circular shape. The electronic screen is configured to show a variety of images. The electronic screen is programmable which allows to depict any image which is beneficial in providing a customisable sensor door button for many different situations.

An improvement is provided in that the electronic screen is positioned at a central region on the front side of the printed circuit board. The at least one detection sensor and the at least one light source are positioned aside the electronic screen. Preferably, a plurality of detection sensors and a plurality of light sources, in particular LEDs, are positioned around the electronic screen. Preferably, at least two detection sensors and at least two light sources are circumventing the electronic screen.

The central position of the electronic screen in between the light sources and detection sensors structurally split technical functions. Providing information to a user and providing visibility of the sensor door button is split by the electronic screen and the light sources.

The sensor door button may be operable by simultaneously operating the at least one light source and the electronic screen. Advantageously, by operating the light source, e.g. by flashing, a colour change or increasing an intensity, a provided message on the electronic screen can be emphasised. A programmed operation of the light source simultaneously with a display of a programmed image may strengthen a particular message to a passenger. For example in a programmed operation, an access logo on the electronic display may be combined with a green coloured light source and a stop logo on the electronic display may be combined with a red coloured light source.

In addition, a sensibility of the sensor door button is improved by providing a detection space from a surrounding of the electronic screen. Herewith, a detection area in front of the sensor door button is enlarged which contributes in intercepting more accurately a finger or hand of a user.

In an embodiment of the sensor door button according to the invention, the printed circuit board is provided with a reflective layer on the front side to increase a reflection of the at least one light source. The reflective layer may comprise a reflection plate. Preferably, the reflective layer is provided by a coating, more in particular a white coating on the front side of the printed circuit board. A front surface of the printed circuit board may at least partially be covered by the reflective layer. For example, a front surface section in which the at least one light source is positioned may be covered by the reflective layer, whilst the central region of the printed circuit board remains uncovered. Preferably, a whole front surface of the printed circuit board is covered by the reflective layer.

In an embodiment of the sensor door button according to the invention, the sensor door button further comprises a light diffuser. The light diffuser is arranged to cover the at least one light source. Typically, instead of e.g. a rectangular shape, the light diffuser has an annular shape which is configured to be positioned around the electronic screen. The light diffuser is arranged to distribute the light evenly. The light diffuser is made of a transparent material. The light diffuser may be made of a coloured transparent material, e.g. a blue or yellow transparent material. Herewith, the presence of the light diffuser advantageously contributes to a modularity of the sensor door button in that the sensor door button can easily be adapted in colour for a particular application by exchanging the light diffuser.

At a rear side, the light diffuser may have at least one recess, in particular a circular slot, for receiving the at least one light source mounted to the printed circuit board. In an assembly, the at least one recess allows the light diffuser to be in abutting engagement with the printed circuit board. The light diffuser may have a thickness which is substantially equal to a thickness of the electronic screen, such that a top surface of the light diffuser lays flush with a top surface of the electronic screen being positioned inside the ring-shaped light diffuser. Beneficially, in assembling the sensor door button to a door window, the top surface of the light diffuser may be adhered to the window panel.

In an embodiment of the sensor door button according to the invention, the sensor door button comprises a control unit for controlling the sensor door button. The control unit may be programmable by a user interface to input an image to be screened on the electronic screen. The image may be a moving image, like a GIF file, a video or a logo. Preferably, the control unit comprises a processor for processing control signals and a memory for storing images. Preferably, the control unit is an on-board control unit which is electronically connected to the printed circuit board holding the electronic screen. The on-board control unit is incorporated in the sensor door button. The control unit may be housed by the sensor door button housing. In particular, the control unit is positioned onto the printed circuit board.

In an embodiment of the sensor door button according to the invention, the control unit is programmed to instantly receive an input, e.g. from a bus driver or sensor, to adapt a displayed image at the electronic screen. The control unit may be electronically connected to a vehicle controller to obtain a signal from the vehicle controller, e.g. a sensor for counting passengers. Beneficially, an input may be provided to change user information displayed on the electronic screen of the sensor door button. For example, on the electronic screen an image may indicate a door opening and closing information to passengers. An image may indicate whether the door is available for use by passengers. In an embodiment, an icon on the electronic screen which indicates to a passenger standing outside that the bus is accessible may be changed to another icon to indicate that no seats are available any more and subsequently to an icon indicating that the bus is full.

In an embodiment of the sensor door button according to the invention, the sensor door button comprises a housing for housing the printed circuit board. The housing may have a circular shape, in particular a cup shape for receiving the printed circuit board inside the cup shape. The cup-shaped housing has a cup bottom and a circumferential cup wall. The cup bottom may have a bottom aperture. The housing may be ring shaped including a bottom rim for supporting the printed circuit board. Preferably, the housing is arranged to house the light diffuser. Preferably, the light diffuser is connectable by a snap connection to the housing. The cup wall may have a wall height in correspondence with a thickness of a stacked printed circuit board and light diffuser. The housing may have a front surface which is arranged to adhere to the window panel of the door.

In an embodiment of the sensor door button according to the invention, the printed circuit board is a double sided printed circuit board. The printed circuit board has a rear side which supports at least one electronic component, like a memory, processor, a communication bus etc .. On the front side, the printed circuit board is provided with the at least one detection sensor, the at least one light source and the electronic screen.

In an embodiment of the sensor door button according to the invention, the double sided printed circuit board comprises a first electronic screen at the front side a second electronic screen at the rear side. Herewith, the sensor door button is arranged to provide information to the user at both the front and rear side of the sensor door button.

In an embodiment of the sensor door button according to the invention, the at least one light source includes a plurality of LEDs, in particular at least four LEDs, more in particular eight or twelve LEDs. The plurality of LEDs are equally spaced around the electronic screen. In particular, the plurality of LEDs comprises at least one blue LED and/or at least one red LED. Preferably, a blue LED and a red LED are paired at a position around the electronic screen. Preferably, the plurality of LEDs comprises a plurality of RGB LEDs to generate any programmed colour.

In an embodiment of the sensor door button according to the invention, the sensor door button comprises a plurality of detection sensors. Preferably, the sensor door button comprises at least four detection sensors. Preferably, the at least four detection sensors are equally spaced around the electronic screen. Herewith, a cumulative detection space formed by the at least four detection sensors is distributed along a contour of the sensor door button and provides a relative large area for detecting the hand and/or finger of a user.

In an embodiment of the sensor door button according to the invention, the sensor door button comprises a light sensor for detecting an environmental light intensity. The control unit of the sensor door button is programmed to adapt a light intensity of the at least one light source in dependence of a detected environmental light intensity. Herewith, the light sensor allows the sensor door button to anticipate on different light intensities, for example for daylight or tinted glazing. Preferably, the light sensor is used to adapt both a brightness of the electronic screen and a light intensity of the at least one light source.

In an embodiment of the sensor door button according to the invention, the at least one detection sensor comprises a capacitive sensor for detecting a hand and/or finger in a capacitive detection space, and/or the at least one detection sensor comprises an optical sensor for detecting a hand and/or finger in an optical sensor detection space, and/or the at least one detection sensor comprises a radar sensor for detecting a hand and/or finger in a radar detection space.

In an embodiment of the sensor door button according to the invention, the sensor door button further comprises a haptic element, in particular a haptic ring. The haptic element is arranged to be attached onto a door window in alignment with a centre line of the electronic screen. Herewith, a user has a tangible marking of the detection space of the sensor door button. Preferably, the haptic element is provided with braille to assist a visually disabled person.

Further, the invention relates to a vehicle door button for opening and closing a vehicle door, e.g. a truck vehicle cabin door, in particular an electric truck vehicle cabin door, more in particular for opening and closing a public passenger vehicle door, like a touring bus door or a train door.

Further, the invention relates to a sensor door button system comprising a sensor door button according to the invention and a control unit, wherein the control unit is electronically connected to a controller of a vehicle, in particular a public passenger vehicle.

In an embodiment of the sensor door button according to the invention, the control unit is electronically connected via a CAN bus. In particular, a two wire CAN communication is provided for operating the sensor door button. The communication bus may be positioned at a rear side of the printed circuit board. The electronic screen of the sensor door button

Further, the invention relates to a method informing passengers for entering a public transport vehicle wherein use is made of a sensor door button system including a programmable electronic screen to display a variety of images. In particular, the sensor door button comprises a step of providing a sensor door button system according to the invention. In a step of the method, passenger information displayed on the electronic screen of the sensor door button is changed based on a drivers input or a sensory output. A vehicle driver may manually change displayed information. Alternatively, displayed information may be changed automatically based on a detected situation by a sensor, e.g. a full occupation of a passengers room. The sensory output of the sensor may be configured to detect all kind of circumstances which are subsequently relevant to determine whether an adaption of the displayed information on the sensor door button.

In an embodiment of the method according to the invention, the displayed passenger information is changed based on a sensor output which determines an amount of passengers present in the public transport vehicle. The sensor door button system may comprise an electronic passenger counter for counting passengers passing the vehicle door. The displayed passenger information is adapted in dependence of counted passengers.

In an embodiment of the method according to the invention, the displayed information may be configured to indicate at least one of the following features:
whether or not all seats are occupied;
whether or not standing room is available in the public transport vehicle.
   The displayed information may indicate to a passenger to use a next door of the public transport vehicle in case no passenger places are available at a particular section. This feature is in particular beneficial for a train to obtain an even passenger distribution over a length of the train.

In an aspect, the invention relates to a method for operating a sensor door button to message a passenger nearby a public transport vehicle by presenting a predetermined image on an electronic screen of the sensor door button. In particular, in the method use is made of a sensor door button and/or sensor door button system according to the invention as described.

In an embodiment of the method according to the aspect of the invention, the method comprises a step of providing passenger information by presenting a predetermined image on the electronic screen of the sensor door button in which a selection of the predetermined image is based on an external input signal. The external input signal may for example originate from a vehicle controller, an external computer device or cloud data. The vehicle controller may operate based on an controller input which may be effected by for example a vehicle sensor, a vehicle driver, a operator computer device.

In an embodiment of the method according to the aspect of the invention, a presentation of the predetermined image is combined with a predetermined setting of at least one light source of the sensor door button. The predetermined setting of the at least one light source may for example include a predetermined intensity, colour, motion, an intensity change, a flashing or a colour change of the light source.

In an embodiment of the method according to the aspect of the invention, a passenger information may be provided by a predetermined image on the electronic screen in combination with a predetermined colour of the at least one light source.

The predetermined image may be selected from an image category, for example functional images relating to an operation of the transport vehicle or non-functional images like for example general, personalised or commercial images for advertising which may include company logos, weather images, like sun or cloud icons or event images, like exhibition logos,

The predetermined image may be a photo picture, an icon, e.g. an emoticon or a symbol. Preferably, the sensor door button system comprises a memory for storing such images. A predetermined image may for example indicate that a door is accessible, wherein in operation the predetermined image can be combined with a green colour of the at least one light source. The predetermined image may for example indicate an inaccessible door, wherein the predetermined image can be combined with a red colour of the at least one light source. A green or red coloured ring-shaped light source may circumvent such an access image to contribute in attracting a passengers attention.

In an embodiment of the method according to the aspect of the invention, a predetermined image to be displayed on the electronic screen is programmed to indicate whether or not a door is accessible, in particular in combination with a programmed predetermined colour, in particular a red colour, of the at least one light source. In particular, a red colour ring-shaped light body is programmed in combination with a programmed image on the electronic screen indicating a non-accessible door. The image on the electronic screen may be programmed to indicate for an accessible door entry, in particular in combination with a programmed predetermined colour, in particular a green colour, of the at least one light source. In particular, a green colour ring-shaped light body is programmed in combination with a programmed image on the electronic screen indicating an accessible door.

In an embodiment of the method according to the aspect of the invention, the predetermined the image on the electronic screen may be programmed to indicate whether or not an access ramp of a door system is deployed.

In an embodiment of the method according to the aspect of the invention, the predetermined image on the electronic screen may be programmed to present a timer indicating that a door is closing. In particular, the image is programmed to be presented in combination with a changing light source, in particular a flashing light source, more in particular a red flashing light source. The combination of the presented image on the electronic screen and changing light source around the electronic screen may be beneficial in warning a passenger that a door is starting to close.

In an embodiment of the method according to the aspect of the invention, the sensor door button system further comprises an electronic passenger counter for counting passengers in which the displayed image is adapted in dependence of counted passengers, in particular to indicate whether a seat or standing room is still available.

In an embodiment of the method according to the aspect of the invention, the at least one light source is programmed to indicate a remaining load capacity of a passenger area in combination with a programmed image on the electronic screen.

In an embodiment of the method according to the aspect of the invention, the control unit is programmed to manage a passenger flow by providing an image on at least one electronic screen of a series of electronic screens of sensor door buttons in an embodiment of the method according to the aspect of the invention to indicate a direction, e.g. to indicate a walking path to a left or right door.

In an embodiment of the method according to the aspect of the invention, the control unit is programmed to present a predetermined image indicating a battery charging status of a vehicle. Preferably, the control unit is electronically connected to a vehicle controller being electronically connected to a sensor to obtain a sensory output for detecting the battery charging status.

In an embodiment of the method according to the aspect of the invention, the control unit is programmed to present a predetermined image on the electronic screen, wherein the predetermined image is selected from a group of non-functional images which may include fun images, like emoticons, business images, like company logos, weather images, like sun, rain or cloud icons and/or personalised images, like jubilee images.

### BRIEF DESCRIPTION OF THE DRAWINGS

The invention will be explained in more detail with reference to the appended drawings. The drawings show a practical embodiment according to the invention, which may not be interpreted as limiting the scope of the invention. Specific features may also be considered apart from the shown embodiment and may be taken into account in a broader context as a delimiting feature, not only for the shown embodiment but as a common feature for all embodiments falling within the scope of the appended claims, in which:

FIG. 1 shows a front view of an embodiment of the sensor door button according to the invention having an electronic screen and an annular illumination positioned behind a window panel;

FIG. 2 shows an exploded view of the sensor door button as shown in FIG. 1;

FIG. 3 shows the exploded view of FIG. 2 in a rear view;

FIG. 4 shows the printed circuit board holding an outer circular array of light sources and an inner circular array of detection sensors;

FIG. 5 shows a double sided embodiment of the sensor door button according to the invention having a first and second electronic screen at respectively a rear and front side; and

FIG. 6 shows an application of the sensor door button in a public transport vehicle.

### DETAILED DESCRIPTION OF THE INVENTION

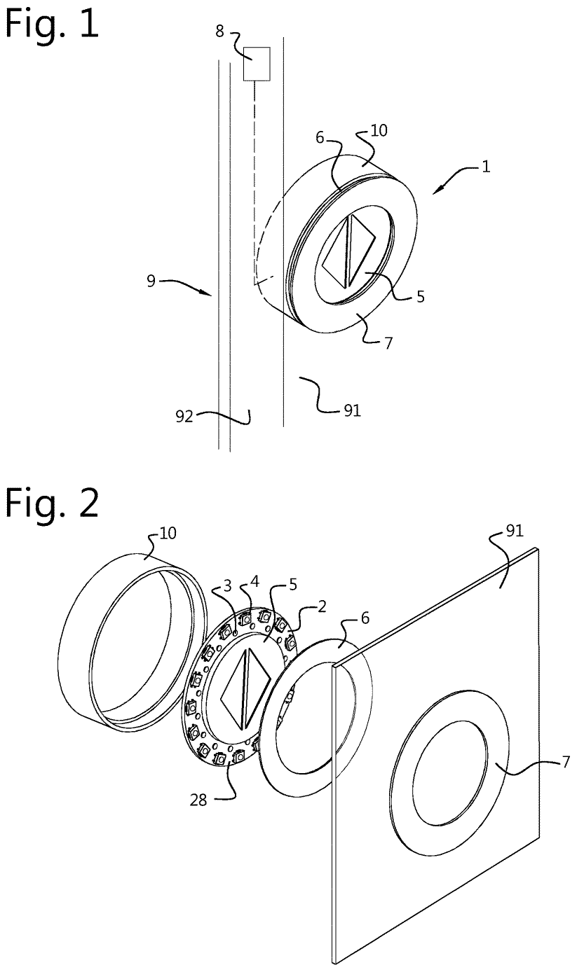

In FIGS. 1-6, a sensor door button according to the invention is denoted overall by reference numeral 1. Identical reference signs are used in the drawings to indicate identical or functionally similar components.

FIG. 1 shows in a frontal perspective view an embodiment of a sensor door button 1 for operating a door. The sensor door button 1 is attachable to an inside of a window panel 91. Here, the sensor door button 1 is positioned behind a window panel 91 of a vehicle door 9. The vehicle door 9 has a door window 90 which has a window panel 91 held by a window frame 92.

The sensor door button 1 has a housing 10 for housing an electronic screen 5 being positioned inside an annular light diffuser 6. The light diffuser 6 covers at least one light source and provides an even illumination. The housing 10 is positioned at a rear side of the window panel 91 of a vehicle door 9. The housing 10 has a front surface for adhering the sensor door button 1 to the window panel. In particular, the light diffuser has a front surface for attaching the light diffuser to the window panel.

As shown, at a front side of the window panel 91, a haptic element 7 may be positioned in alignment with the housing 10 behind the window panel. The haptic element provides a tangible marking of a detection space of the sensor door button. The haptic element may be provided with braille to assist visually disabled person in operating the sensor door button 1.

Here, the haptic element 7 is ring-shaped. The haptic element 7 is made of a transparent material and sized in correspondence with the housing 10 behind the window panel. The electronic screen 5 is visible at the inner side of the haptic element 7 and the haptic element is illuminated by the light source.

The sensor door button 1 has a wired connection with a control unit 8. The control unit 8 is configured to control the sensor door button 1. The sensor door button 1 has a cable connection which is here extending through a window frame 92 of the door window 90.

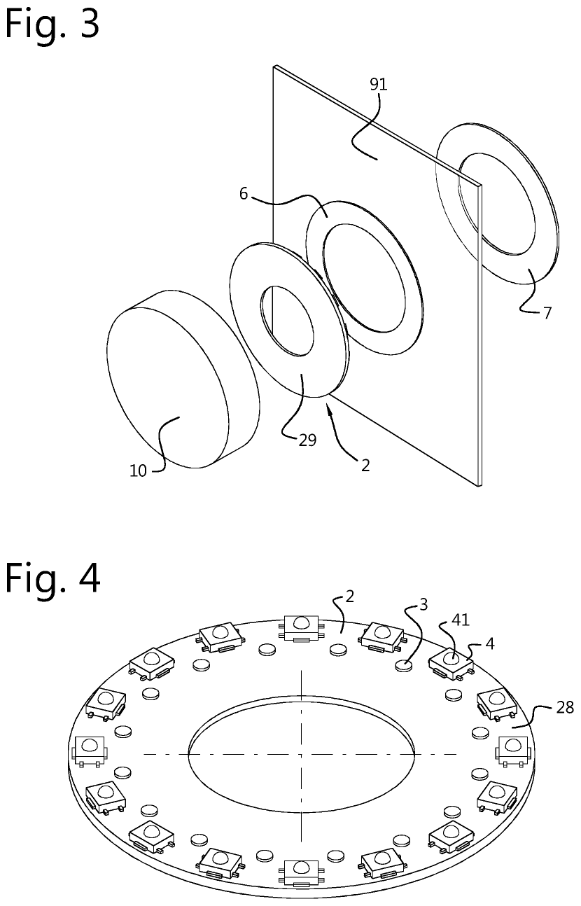

FIGS. 2 and 3 show an exploded view of the sensor door button 1 in respectively a frontal and rear perspective view. The housing 10 is cup-shaped. The cup-shaped housing 10 has a bottom plate and an open front side. Inside, the housing has a bottom rim for supporting a printed circuit board (PCB) 2. In an assembly, a rear side 29 of the PCB 2 is in abutting engagement with the bottom rim of the housing 10.

In particular, the light diffuser 6 is connectable by a snap connection to the PCB 2 or housing 10. Preferably, the light diffuser is connectable to the PCB to form a subassembly to be placed inside the housing 10. The light diffuser may be made of any transparent material, for example a polycarbonate material. Preferably, the light diffuser is made of a coloured transparent material to provide a coloured elimination. The snap connection of the light diffuser to the housing or PCB is beneficial in substituting a light diffuser 6 in case another colour of illumination is preferred.

As further shown in FIG. 4, the PCB 2 is arranged for supporting electronic components on a front side 28. The PCB has an electric circuit on the front side 28 for connecting at least one detection sensor 3, at least one light source 4 and an at least one electronic screen 5. Here, at the front side 28, at an outer region, the PCB 2 supports a plurality of detection sensors 3 and light sources 4, and at an inner region, the PCB supports a circular electronic screen 5.

The at least one detection sensor 3 is arranged to detect a presence of a hand or a finger in a detection space. The detection space extends to a front side of the sensor door button. The at least one light sensor 4 is arranged to illuminate an environment at the front side of the sensor door button.

The light sources 4 comprise an outer circular array of LEDs 41. The plurality of detection sensors 3 are positioned at a ring-shaped region of the PCB inside a ring-shaped region in which the LEDs are positioned. The plurality of detection sensors 3 are arranged in a circular array inside the outer circular array of LEDs 41.

Further, the PCB has a central region which is configured to connect the electronic screen 5. The electronic screen serves to provide information to a user. In operation, the electronic screen 5 may display an image, in particular a moving image, a logo or an icon.

Both the plurality of detection sensors 3 and the light sources 4 are positioned outside this central region. The plurality of detection sensors 3 and light sources 4 surround the electronic screen 5. The light sources 4 covered by the light diffuser 6 provide a ring of light around the electronic screen 5. In particular, the light diffuser 6 has a ring thickness which is substantially equal to the thickness of the electronic screen. Herewith, the subassembly of the PCB 2, the electronic screen 5 and the light diffuser 6 has a constant thickness which contributes to an attachment of the sensor door button to the window panel.

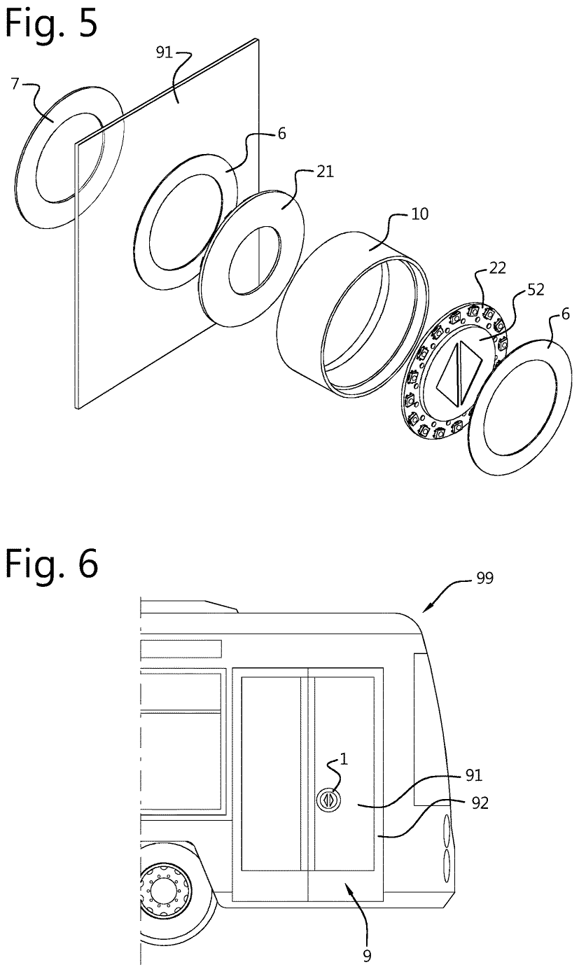

In FIG. 5, a double sided sensor door button 1 is shown. Here, the double sided sensor door button 1 has a first electronic screen 51 connected to a first PCB 21 and a second electronic screen 52 connected to a second PCB 22. In addition to the first electronic screen 51 which provides information to a front side of the door, the second electronic screen 52 provides information to a user being situated at a back side of the door. Herewith, the double sided sensor door button 1 provides information to both sides of the door. The housing 10 is ring-shaped. The housing 10 has an inner rim for supporting the first PCB 21 at a front side and the second PCB 22 at a rear side. Each PCB is covered by a light diffuser 6.

In FIG. 5, the first and second PCB 21, 22 are shown as separate items. In an alternative embodiment of a double sided sensor door button, it is conceivable to provide a double sided PCB which incorporates the first and second PCB. The double sided PCB supports the first electronic screen 51 at a front side and the second electronic screen 52 at a rear side.

FIG. 6 shows a public transport vehicle 99, here a bus vehicle, which has a sensor door button 1 according to the invention attached to a window panel 91 of a door window 90.

The sensor door button 1 is in particular beneficial in a public transport vehicle 99 to carry out a method in which a variety of information is presented to a passenger. In the method, a step is carried out in which a provided passenger information is substituted by other passenger information, for example by changing an icon to another icon.

Numerous variants are possible in addition to the embodiment shown in the figures. Although the present invention has been described in detail, it will be apparent to those skilled in the art that various changes and modifications can be made without departing from the scope of the invention as hereinafter claimed. It is intended that all such changes and modifications be encompassed within the scope of the present disclosure and claims.

Further, it is remarked that any feature of the system according to the invention which is described in the embodiments and/or mentioned in the dependent claims is in itself considered patentable without any dependency to another presented feature. In particular, any measure presented in a dependent claim is also considered patentable without dependency of the independent claim.

Thus, the invention provides a sensor door button being attachable to a window panel which comprises a printed circuit board for supporting at least one detection sensor, at least one light source and an electronic screen on a front side. The detection sensor is configured for detecting a presence of a hand and/or a finger in a detection space and the light source for illuminating an environment at a front side of the sensor door button. The electronic screen is configured to provide information to a user. The electronic screen is positioned at a central region on the front side of the printed circuit board and the detection sensor and the light source are positioned around the electronic screen.

### REFERENCE SIGNS LIST

1 sensor door button
10 housing
2 printed circuit board; PCB
21 first PCB
22 second PCB
28 front side
29 rear side
3 detection sensor
4 light source
41 LED
5 electronic screen
51 first electronic screen
52 second electronic screen
6 light diffuser
60 diffuser ring
7 haptic element
8 control unit
9 vehicle door
90 door window
91 window panel
92 window frame
99 bus vehicle

1. A sensor door button for operating a door and being attachable to a window panel of the door, which sensor door button comprises:
a printed circuit board for supporting electronic components which printed circuit board has an electric circuit on a front side for electrically connecting electronic components, wherein the electronic components comprise;
at least one detection sensor for detecting a presence of a hand and/or a finger in a detection space, in which the at least one detection sensor is positioned on the front side of the printed circuit board;
at least one light source, in particular a LED, for illuminating an environment at a front side of the sensor door button in which the at least one light source is positioned on the front side of the printed circuit board; and
a programmable electronic display, in particular an electronic screen, for providing information to a user by displaying any image, like a logo or an icon, wherein the electronic display is distinct from the at least one detection sensor and distinct from the at least one light source and wherein the electronic display is positioned at a central region on the front side of the printed circuit board, wherein the at least one detection sensor and the at least one light source are positioned around the electronic display.

2. The sensor door button according to claim 1, wherein a reflective layer, in particular a coating, more in particular a white coating, is provided on the front side of the printed circuit board to increase a reflection of the at least one light source

3. The sensor door button according to claim 1 comprising a light diffuser for covering the at least one light source, which light diffuser has an annular shape which is configured to be positioned around the electronic screen.

4. The sensor door button according to claim 3 comprising a housing for housing the printed circuit board and the light diffuser, wherein the housing and/or the light diffuser has a front surface for adhering the sensor door button to a window panel of a door, wherein in particular the light diffuser is connectable by a snap connection to the PCB or housing.

5. The sensor door button according to claim 2, wherein the light diffuser has a thickness which is adapted to a thickness of the electronic screen, such that a front surface of the light diffusion is in alignment with a front surface of the electronic screen.

6. The sensor door button according to claim 2, wherein the light diffuser is made of a transparent material, in particular of a polycarbonate material, more in particular a coloured transparent material for providing a coloured illumination.

7. The sensor door button according to claim 2, wherein the light diffuser has a front surface which is attachable to a window panel, in particular to a window panel of a bus door window.

8. The sensor door button according to claim 1, wherein the printed circuit board is a double sided printed circuit board which has a rear side wherein the electronic components to control the sensor door button are attached to the rear side.

9. The sensor door button according to claim 8, wherein the printed circuit board supports a first electronic screen at the front side and a second electronic screen at the rear side of the printed circuit board.

10. The sensor door button according to claim 1, wherein the at least one light source includes a plurality of LEDs, in particular at least four LEDs, more in particular eight or twelve LEDs which are positioned around the electronic display.

11. The sensor door button according to claim 1, wherein the sensor door button comprises a plurality of detection sensors, in particular at least four detection sensors which are in particular equally spaced around the electronic screen.

12. The sensor door button according to claim 1, wherein the electronic screen has a circular shape.

13. The sensor door button according to claim 1, wherein the sensor door button has a control unit, in particular an onboard control unit electrically connected to the printed circuit board, which is programmed to instantly receive an input, e.g. from a bus driver or sensor, for example from a passenger counter, to adapt a displayed image at the electronic screen.

14. The sensor door button according to claim 1, wherein the sensor door button comprises a light sensor for detecting an environmental light intensity, and wherein the control unit is programmed to adapt a light intensity of the at least one light source in dependence of a detected environmental light intensity.

15. The sensor door button according to claim 1, wherein the sensor door button further comprises a haptic element, in particular a haptic ring, to be attached in alignment with a centre line of the electronic screen at an outside of the door window.

16. A sensor door button system comprising a sensor door button according to claim 1 and a control unit, wherein the control unit is electronically connectable to a controller of a public transport vehicle, such that the sensor door button is operable by an output signal from the controller, e.g. by an output signal based on a sensory output of a sensor, for example a sensory output from an electronic passenger counter.

17. A public transport vehicle including at least one sensor door button according to claim 1 for opening or closing a vehicle door, wherein the at least one sensor door button is positioned at a vehicle door, in particular attached to a window panel of a door window of the public transport vehicle.

18. A method for operating a sensor door button to message a passenger nearby a public transport vehicle by selecting and displaying a predetermined image on an electronic screen of the sensor door button in combination with a predetermined setting of at least one light source of the sensor door button.

19. The Method according to claim 18, wherein the predetermined image is selectable from a functional category of images relating to vehicle operation, wherein in particular the images are stored in a memory of the sensor door button.

20. The Method according to claim 18, wherein a displayed image on the electronic screen of the sensor door button is changed based on an external input signal which in particular originates from a vehicle controller.

21. The Method according to claim 18, wherein the vehicle controller is electronically connected to a sensor to obtain a sensory output for detecting a predetermined circumstance to select the predetermined image to adapt passenger information.
